(19) United States
(12) Patent Application Publication
(10) Pub. No.: US 2008/0197294 A1
(43) Pub. Date: Aug. 21, 2008

(54) MANUFACTURING METHOD OF CIRCUIT BOARD

(75) Inventor: Toyoaki SAKAI, Nagano-shi (JP)

Correspondence Address: DRINKER BIDDLE & REATH (DC), 1500 K STREET, N.W., SUITE 1100, WASHINGTON, DC, 20005-1209, US

(73) Assignee: SHINKO ELECTRIC INDUSTRIES CO., LTD., Nagano-shi (JP)

(21) Appl. No.: 12/030,543

(22) Filed: Feb. 13, 2008

(30) Foreign Application Priority Data
Feb. 14, 2007 (JP) 2007-033656

(51) Int. Cl. G03F 7/20

(52) U.S. Cl. 250/492.2

(57) ABSTRACT

An exposure method includes: (a) providing a substrate coated with a photosensitive material on a stage; and (b) applying a spot light beam emitted from a light source to the photosensitive material while moving the stage in accordance with a previously programmed exposure pattern for wiring formation, thereby performing pattern exposure of the photosensitive material. In the exposure method, the spot light beam is controlled so that the spot light beam is formed into an ellipse whose major axis is in a direction perpendicular to a move direction of the stage.

This application is based on and claims priority from Japanese Patent Application No. 2007-033656, filed on Feb. 14, 2007, the entire contents of which are hereby incorporated by reference.

### BACKGROUND OF THE INVENTION

1. Technical Field

The present disclosure relates to a maskless exposure method without using a mask, and also relates to a manufacturing method of a circuit board using the maskless exposure method, wherein a pattern corresponding to a predetermined wiring pattern to be formed on a board is formed on a photosensitive resin surface of the board through exposure when a circuit board is manufactured.

2. Background Art

In recent years, demand for maskless exposure without using mask has been increased. Hitherto, a Laser Direct Imaging (LDI) device using a Digital Micro Device (DMD) has been proposed as a method of performing maskless exposure. In the LDI device, light emitted from a light source such as a laser diode is program-controlled and is reflected by the DMD. Then, the light passes through a plurality of lenses and is applied to a photosensitive resin. Light reflected by a mirror is reflected as a small spotlight respectively and is applied to the photosensitive resin.

In the LDI structure, a stage is moved for patterning the photosensitive resin thereon. The irradiated light is reflected by the DMD, whereby pattern exposure is performed. However, drag of light relative to the move direction of the stage occurs because the stage is moved for performing pattern exposure as described above. Therefore, a difference occurs between the dimensions after patterning in a direction perpendicular and a direction parallel to the stage moving direction.

FIG. 1 is a schematic view showing a state where light is applied to a photosensitive resin of a dry film resist, etc., as concentric spots in a Laser Direct Imaging (LDI) device using a DMD. In FIG. 1, arrow “A” shows the move direction of a stage. In order to form a printed wiring circuit, a substrate coated with a photosensitive resin 10 such as a dry film resist is provided on the stage. “S” indicates the cross-sectional shape of light spots applied to the stage. In order to irradiate the photosensitive resin 10 with a light beam and expose the photosensitive resin 10 to light, a large number of light spots must be concentrated more than a predetermined light amount. In the related-art, the cross-sectional shape of each light spot is concentric and a large number of light spots are arranged.

To simplify the description, it is assumed that the wiring pattern formed on the substrate is, for example, a pattern 12 substantially shaped like L-shape, and that a vertical line parallel with the move direction of the stage is a pattern portion 12a, and that a horizontal line perpendicular to the move direction of the stage is a pattern portion 12b. When exposure is performed according to the pattern, the portion 12 becomes an exposure portion and any other portion denoted by numeral 13 becomes a non-exposure portion.

If the light shape is concentric, dimension a (μm) of the width of the vertical line pattern portion 12a is substantially similar to the design dimension; for example, it is 10 μm. However, since a pattern exposure method based on the premise that the stage moves in the arrow “A” direction is adopted, the exposure line width is thickened because of drag of light in the region of the horizontal line pattern portion 12b with a thin line width. In this case, the horizontal line pattern portion 12b in FIG. 1 shows a state in which the exposure line width is thickened because of drag of light, and the width of the horizontal line pattern portion 12b becomes b times the width a (μm) of the vertical line pattern portion 12a, where b is 1 or more. That is, the width (w) of the horizontal line pattern portion 12b is represented by the following relationship:

Width(w)=a×b μm(1.0<b)

Thus, drag of light occurs in the stage moving direction in the related-art where pattern exposure is performed while moving the stage. Accordingly, a difference occurs between the dimensions after patterning in the perpendicular direction and the parallel direction to the stage moving direction. (see e.g., JP-A-2003-337426 and JP-A-2003-337427).

In JP-A-2003-337426, a problem is as follows: In an exposure device having a light amount detector for detecting the light amount of an exposure beam before exposure start so that the light amount becomes uniform when scan exposure is performed with the exposure beam, the number of light amount detectors is decreased and the circuit configuration of a processing circuit is simplified while accuracy of the light amount detection is kept constant. Thus, the exposure device has a conductive sheet member including: a beam incidence face extending in one direction in accordance with the extension direction of an exposure beam; and a beam emission face where the shape of the beam incidence face becomes deformed and the width of the beam incidence face in the extension direction becomes narrow, and causes the exposure beam from the beam emission face to converge on the light reception face of the light amount detector.

In JP-A-2003-337427, a problem is as follows: In an exposure device using a light beam for exposing a photosensitive material, a light amount distribution can be obtained in a short time without using a two-dimensional light detector and further a processing circuit for obtaining the light amount distribution is simplified. Thus, the exposure device includes a control unit and a light amount detection unit. The control unit controls the drive mode for switching multiple beams projected onto a predetermined area from a plurality of adjacent micromirrors between an exposure ON state and an exposure OFF state alternately in batch at a drive frequency determined in response to the area. The light amount detection unit detects the light amount of light in either of the exposure ON state and the exposure OFF state in the drive mode and then generates a light amount detection signal.

As described above, the laser direct imaging (LDI) device adopts the structure where a stage is moved for patterning a photosensitive resin on the stage. Light is applied onto the moving stage, whereby pattern exposure is performed. However, drag of light occurs in the move direction of the stage because pattern exposure is performed while moving the stage. Therefore, a difference occurs between the dimensions after patterning in the perpendicular direction and the parallel direction to the stage moving direction. Neither JP-A-2003-337426 nor JP-A-2003-337427 discloses any solution to the problem as for drag of light relative to the move direction of the stage.

### SUMMARY OF THE INVENTION

An object of the exemplary embodiments provides an exposure method in which drag of light relative to the stage moving direction can be eliminated even in a laser direct imaging (LDI) where the stage is moved, and thus no difference occurs between the dimensions after patterning in the perpendicular direction and the parallel direction to move direction of the stage. Accordingly, in the exposure method, the designed dimension of a wiring width can be obtained. Further, an object of the exemplary embodiments provides a manufacturing method of a circuit board using the exposure method.

In order to achieve the foregoing object, according to one or more aspects of the exemplary embodiments, an exposure method includes:

(a) providing a substrate coated with a photosensitive material on a stage; and

(b) applying a spot light beam emitted from a light source to the photosensitive material while moving the stage in accordance with a previously programmed exposure pattern for wiring formation, thereby performing pattern exposure of the photosensitive material, wherein

the spot light beam is controlled so that the spot light beam is formed into an ellipse whose major axis is in a direction perpendicular to a move direction of the stage.

According to another aspect of the exemplary embodiments, the light source may be a semiconductor laser, the spot light beam may be an ultraviolet light, and the step of controlling the spot light beam may include:

(i) reflecting the spot light beam using a two-dimensional space modulator of a digital micro device; and

(ii) adjusting a focus-to-focus distance between a reflecting focus of the digital micro device and a focus of the photosensitive material on the stage.

According to another aspect of the exemplary embodiments, the photosensitive material may be subjected to pattern exposure by adjusting a focus-to-focus distance between a reflecting surface of a digital micro device for reflecting the spot light beam and the photosensitive material coated on the substrate, and a dimension error of the photosensitive material after development may be minimized in the direction perpendicular to and a direction parallel to the move direction of the stage using an optical system coordinate axis.

According to another aspect of the exemplary embodiments, an exposure method includes:

(a) providing a substrate coated with a photosensitive material on a stage; and

(b) applying a light beam emitted from a light source to the photosensitive material while moving the stage in accordance with a previously programmed exposure pattern for wiring formation, thereby performing pattern exposure of the photosensitive material, wherein

the previously programmed exposure pattern thins a wiring portion formed in a direction perpendicular to a move direction of the stage at a predetermined ratio as compared with a wiring portion formed in a direction parallel to the move direction of the stage.

According to another aspect of the exemplary embodiments, a shape of the light beam applied to the stage may be concentric.

According to another aspect of the exemplary embodiments, a manufacturing method of a circuit board includes: forming a wiring pattern using the exposure method. In this case, after a dry film resist on the substrate is exposed, development is performed and then a copper pattern is formed on the removed portion of the resist corresponding to the wiring pattern by e.g., plating.

According to another aspect of the exemplary embodiments, there is provided a computer-readable medium having an exposure pattern program stored thereon and readable by a computer,

the exposure pattern program, executed by the computer when a light beam emitted from a light source is applied to a photosensitive material on a substrate that is provided on a stage moving in accordance with a previously programmed exposure pattern for wiring formation, causes the computer to perform operations comprising:

thinning a wiring portion formed in a direction perpendicular to a move direction of the stage at a predetermined ratio as compared with a wiring portion formed in a direction parallel to the move direction of the stage.

According to the exemplary embodiments, the spot light beam is controlled so that the spot light beam applied to the photosensitive material is formed into an ellipse whose major axis is in the direction perpendicular to the move direction of the stage. Also, the pattern exposure is performed using the program of the exposure pattern for thinning the wiring portion formed in the direction perpendicular to the move direction of the stage at a predetermined ratio as compared with the wiring portion formed in the direction parallel to the move direction of the stage. Accordingly, it is possible to eliminate drag of light relative to the move direction of the stage and obtain an exposure pattern having a wiring width causing no difference to occur between the dimensions after patterning in the perpendicular direction and the parallel direction to move direction of the stage even in the laser direct imaging (LDI) device where a stage is moved.

### BRIEF DESCRIPTION OF THE DRAWINGS

In the accompanying drawings:

FIG. 1 is a schematic view showing an exposure method according to a related art;

FIG. 2 is a schematic view showing an exposure method according to a first embodiment of the present invention;

FIG. 3 is a schematic view showing an exposure method according to a second embodiment of the present invention;

FIG. 4 shows overviews of patterning according to a related art and the first embodiment of the invention (example 1);

FIGS. 5A to 5C show the dimension results of patterning according to a related art and the first and second embodiments of the present invention (examples 1 and 2); and

FIG. 6 is a schematic view showing the laser direct imaging (LDI) device according to the present invention.

### DETAILED DESCRIPTION OF EXEMPLARY EMBODIMENTS

Embodiments of the present invention will be described in detail with reference to the accompanying drawings.

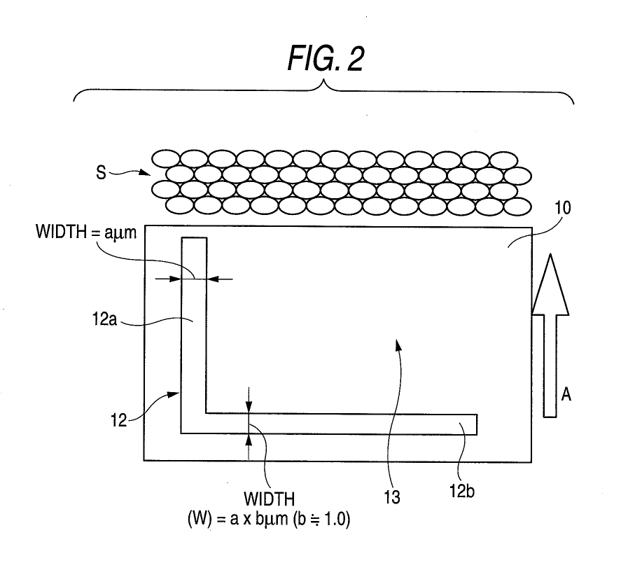

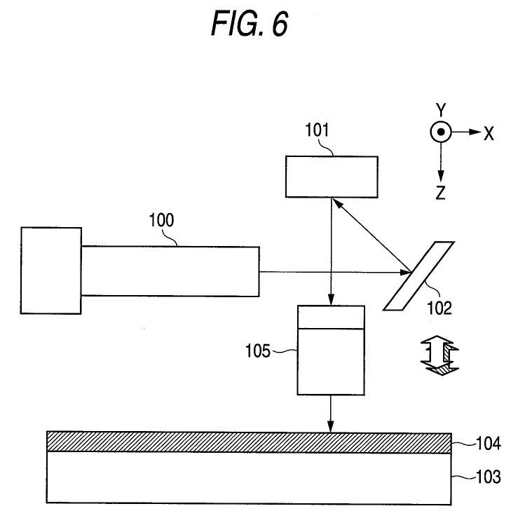

FIG. 2 is a schematic view showing a first embodiment of the present invention. FIG. 6 is a schematic view showing the laser direct imaging (LDI) device according to the present invention.

A light source is a semiconductor laser (in FIG. 6, a laser diode 100) and light emitted from the light source is ultraviolet light and is reflected to a digital micro device (in FIG. 6, a DMD 101) trough a mirror 102. The light beam reflected by the DMD 101 is controlled so as to become an ellipse whose major axis is in a perpendicular direction to a move direction A of a stage. In FIG. 2, a light beam S is an aggregate of regular arrangement of a large number of light spots each being elliptical in cross section.

A substrate (in FIG. 6 a substrate 103) used for a printed wiring circuit of a semiconductor to be manufactured is provided on the stage and a photosensitive resin such as a dry film resist (in FIG. 6, a DFR 104) is coated on the substrate and the substrate moves at predetermined speed in the arrow “A” direction together with the stage. On the other hand, a light beam applied to the photosensitive resin like a spot is controlled so that each light spot becomes an ellipse whose major axis is in the perpendicular direction to the stage moving direction and whose minor axis is in the parallel direction to the stage moving direction by adjusting the angle of the light beam reflected by the DMD or adjusting Z axis of a lens group 105 with respect to the stage face (XY face). In order to control the ellipse of the cross section of each light spot, for example, the light beam is controlled while e.g., the reflection angle of the light beam on the DMD is observed with e.g., a camera attached onto the stage.

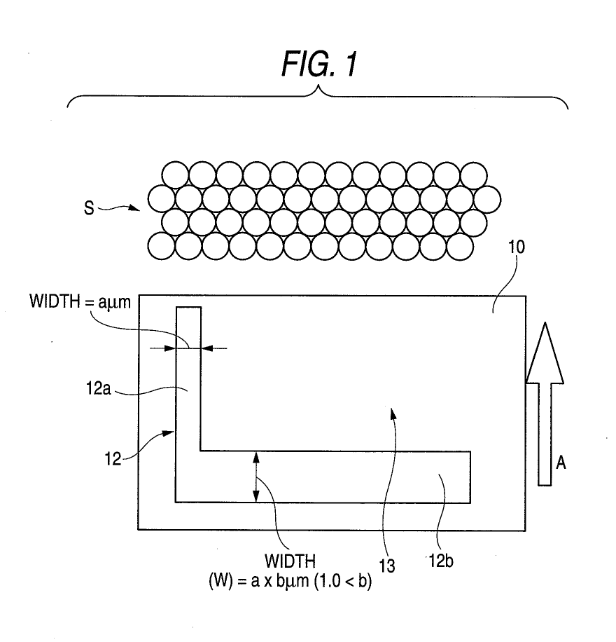

To simplify the description, it is assumed that the wiring pattern formed on the substrate is e.g., a pattern 12 substantially shaped like a “L”, that a vertical line parallel with the move direction of the stage is a pattern portion 12a, and that a horizontal line perpendicular to the move direction of the stage is a pattern portion 12b as with the case in FIG. 1. If exposure is performed in accordance with the pattern, the portion 12 becomes an exposure portion and any other portion denoted by numeral 13 becomes a non-exposure portion.

In the first embodiment of the present invention, the cross-sectional shape of each of the spot light beam is formed like a horizontally oriented ellipse as described above and pattern exposure is performed in this state. Consequently, the difference of the line width dimension of the line pattern resulting from performing the pattern exposure becomes a very small value between the vertical line exposure pattern portion 12a and the horizontal line exposure pattern portion 12b.

That is, in the first embodiment, the width (w) of the horizontal line pattern portion 12b is represented by the following relationship:

Width(w)=a×b μm, where b≈1.0.

Thus, according to the first embodiment of the present invention, a difference scarcely occurs between the dimensions after patterning in the perpendicular direction and the parallel direction to the stage moving direction.

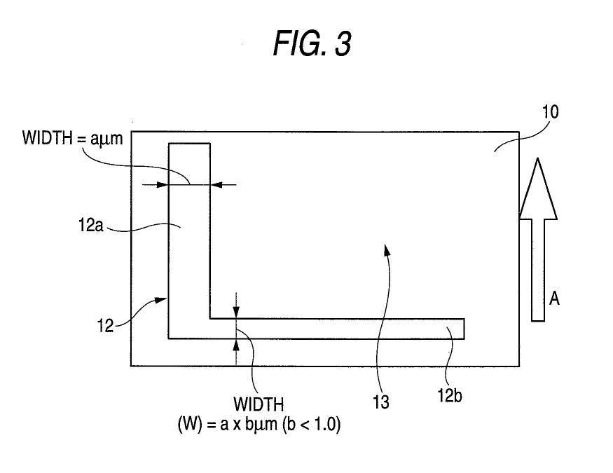

FIG. 3 is a schematic view showing a second embodiment of the present invention.

Also in the second embodiment like the first embodiment described above, a light source is a semiconductor laser (in FIG. 6, the laser diode 100) and light emitted from the light source is ultraviolet light and is reflected to a digital micro device (in FIG. 6, the DMD 101) through the mirror 102. The light beam reflected by the DMD 101 is applied to a stage. FIG. 3 is a schematic view showing a program of an exposure pattern.

A substrate (in FIG. 6, the substrate 103) used for a printed wiring circuit of a semiconductor to be manufactured is provided on the stage and a photosensitive resin such as a dry film resist (in FIG. 6, the DFR 104) is coated on the substrate and the substrate moves at predetermined speed in the arrow “A” direction together with the stage.

On the other hand, in the second embodiment, pattern exposure is performed using a program of an exposure pattern for thinning a wiring portion formed in a direction perpendicular to the move direction of the stage at a predetermined ratio as compared with a wiring portion formed in a direction parallel to the move direction of the stage.

Thus, in the second embodiment of the present invention, a dimension difference is previously provided between the vertical and horizontal lines of a programmed pattern, so that it is possible to eliminate a dimension error after actual pattern exposure in a vertical line exposure pattern portion 12a and a horizontal line exposure pattern portion 12b. That is, it is preferable that the program should be designed for thinning the horizontal line as compared with the vertical line relative to the move direction of the stage in view of eliminating drag of light relative to the move direction of the stage.

That is, in the second embodiment, the width (w) of the horizontal line pattern portion 12b is represented by the following relationship:

Width(w)=a×b μm, where b<1.0.

Thus, according to the second embodiment of the present invention, the dimensions after patterning are programmed considering drag of light as the stage moves, so that a substantial difference scarcely occurs between the dimensions in the perpendicular direction and the parallel direction to the Stage moving direction.

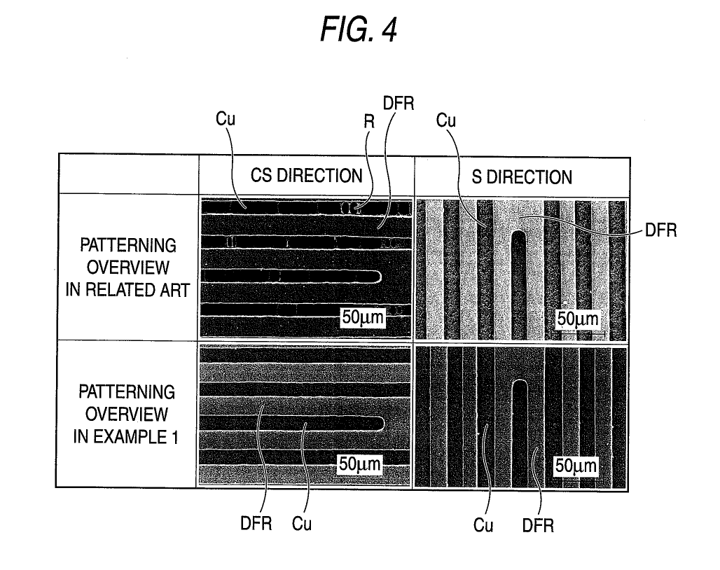

FIG. 4 shows overviews of patterning according to a related art and the first embodiment of the present invention (example 1). In FIG. 4, cross scan (CS) direction means a lateral direction perpendicular to the move direction of the stage, and scan (S) direction means a longitudinal direction parallel to the move direction of the stage. In FIG. 4, the portion of Cu is a portion where a copper pattern is formed, and the portion of DFR is a portion where a dry film resist is exposed. As shown in the figure, it is understood that residue R of the dry film resist remains in the area where the copper wiring pattern is to be formed particularly in the cross scan (CS) direction and exposure is insufficient in the related art.

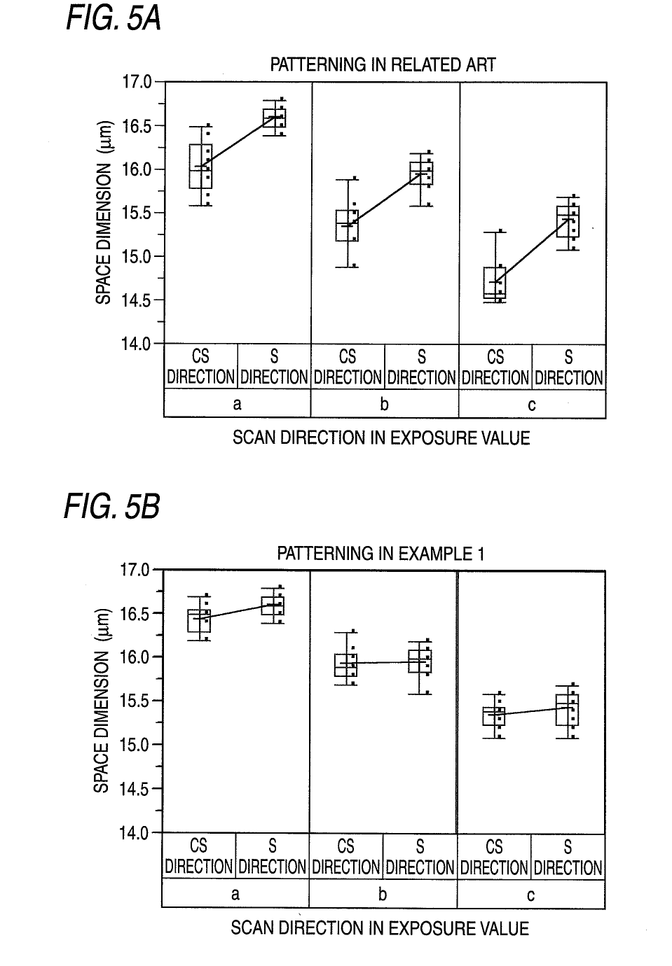

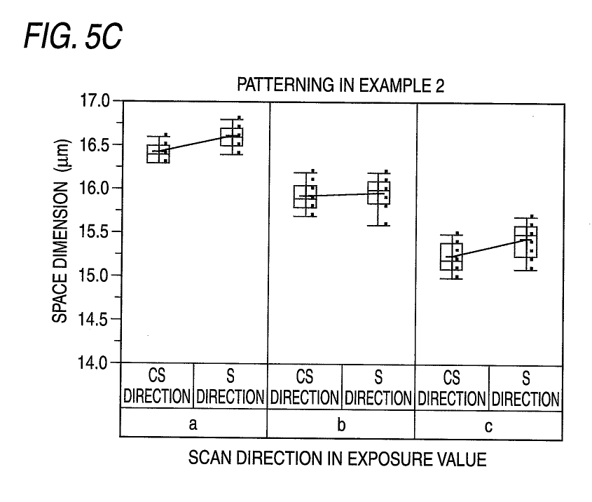

FIGS. 5A to 5C show the dimension results of patterning according to a related art and the first and second embodiments of the present invention (examples 1 and 2). FIG. 5A shows the result of the related art, FIG. 5B shows the result of the first embodiment of the invention (example 1), and FIG. 5C shows the result of the second embodiment of the present invention (example 2). In FIGS. 5A to 5C, the vertical axis indicates the space dimension (am) between patterns. “a” is an area where exposure value is small, “c” is an area where exposure value is large, and “b” is an area where exposure value is about intermediate between “a” and “c”.

As understood from FIGS. 5A to 5C, in the related art, variations in space between patterns are large in the CS direction and the S direction and further the difference between the variations in the CS direction and the variations in the S direction is also large. In contrast, example 1 or 2 of the present invention, variations in space between patterns are small in the CS direction and the S direction and further the difference between the variations in the CS direction and the variations in the S direction is also small. The relationship between the exposure values “a” to “c” and average differences between pattern-to-pattern spaces is listed in the following table.

TABLE 1
Average differences in S direction and CS direction

| Exposure value | Related art | Example 1 | Example 2 |
|---|---|---|---|
| “a” | 0.57 μm | 0.17 μm | 0.19 μm |
| “b” | 0.57 μm | 0.02 μm | 0.04 μm |
| “c” | 0.71 μm | 0.09 μm | 0.20 μm |

In examples 1 and 2, as compared with the related art, the average differences are small and particularly in the exposure value intermediate area “b”, the average differences are extremely small and the variations are small. Therefore, in this area, a stable exposure pattern width can be provided.

While there has been described in connection with the exemplary embodiments of the present invention, it will be obvious to those skilled in the art that various changes and modification may be made therein without departing from the present invention. It is aimed, therefore, to cover in the appended claim all such changes and modifications as fall within the true spirit and scope of the present invention.

As described above, in the maskless exposure method without using a mask according to the present invention, it is possible to eliminate drag of light relative to the move direction of the stage and obtain a wiring width causing no difference to occur between the dimensions after patterning in the perpendicular direction and the parallel direction to the stage moving direction in the laser direct imaging (LDI) device where a stage is moved. Therefore, the maskless exposure method of the present invention can be used for wide applications such as manufacturing of various printed boards, manufacturing of various semiconductor packages, etc.

What is claimed is:

1. An exposure method comprising:
(a) providing a substrate coated with a photosensitive material on a stage; and
(b) applying a spot light beam emitted from a light source to the photosensitive material while moving the stage in accordance with a previously programmed exposure pattern for wiring formation, thereby performing pattern exposure of the photosensitive material, wherein
the spot light beam is controlled so that the spot light beam is formed into an ellipse whose major axis is in a direction perpendicular to a move direction of the stage.

2. The exposure method of claim 1, wherein
the light source is a semiconductor laser,
the spot light beam is an ultraviolet light, and
said step of controlling the spot light beam, comprises:
(i) reflecting the spot light beam using a two-dimensional space modulator of a digital micro device; and
(ii) adjusting a focus-to-focus distance between a reflecting focus of the digital micro device and a focus of the photosensitive material on the stage.

3. The exposure method of claim 1, wherein
the photosensitive material is subjected to pattern exposure by adjusting a focus-to-focus distance between a reflecting surface of a digital micro device for reflecting the spot light beam and the photosensitive material coated on the substrate, and
a dimension error of the photosensitive material after development is minimized in the direction perpendicular to and a direction parallel to the move direction of the stage using an optical system coordinate axis.

4. An exposure method comprising:
(a) providing a substrate coated with a photosensitive material on a stage; and
(b) applying a light beam emitted from a light source to the photosensitive material while moving the stage in accordance with a previously programmed exposure pattern for wiring formation, thereby performing pattern exposure of the photosensitive material, wherein
said previously programmed exposure pattern thins a wiring portion formed in a direction perpendicular to a move direction of the stage at a predetermined ratio as compared with a wiring portion formed in a direction parallel to the move direction of the stage.

5. The exposure method of claim 4, wherein
a shape of the light beam applied to the stage is concentric.

6. A manufacturing method of a circuit board comprising:
forming a wiring pattern using the exposure method of claim 1.

7. A computer-readable medium having an exposure pattern program stored thereon and readable by a computer,
said exposure pattern program, executed by the computer when a light beam emitted from a light source is applied to a photosensitive material on a substrate that is provided on a stage moving in accordance with a previously programmed exposure pattern for wiring formation, causes the computer to perform operations comprising:
thinning a wiring portion formed in a direction perpendicular to a move direction of the stage at a predetermined ratio as compared with a wiring portion formed in a direction parallel to the move direction of the stage.
